(19) United States
(12) Patent Application Publication
(10) Pub. No.: US 2020/0245479 A1
(43) Pub. Date: Jul. 30, 2020

(54) COMPUTER SYSTEM, RETAINING DEVICE AND ASSEMBLY METHOD FOR AN ADD-ON BOARD IN A COMPUTER SYSTEM

(71) Applicant: Fujitsu Client Computing Limited, Kawasaki (JP)

(72) Inventors: Michael Schmid, München (DE); Harald Lugert, München (DE); Willi Sterzik, München (DE); Matthias Krauter, München (DE); Albert Jiang, München (DE)

(21) Appl. No.: 16/756,700

(22) PCT Filed: May 2, 2019
(86) PCT No.: PCT/EP2019/061278

§ 371 Date: Apr. 16, 2020

(30) Foreign Application Priority Data
Jul. 18, 2018 (DE) 10 2018 117 382.2

(51) Int. Cl. H05K 5/00; H05K 5/03; H05K 5/02; H05K 7/14

(52) U.S. Cl. CPC H05K 5/0026; H05K 5/03; H05K 7/1417; H05K 7/1422; H05K 5/0247

(57) ABSTRACT

A computer system includes a casing having at least one casing wall, the at least one casing wall including a first recess for attaching a first add-on board having a first height profile; a system board arranged in the casing and extending perpendicular to the at least one casing wall, the first recess in the at least one casing wall extending perpendicular to the system board; and a retaining device adapted to be fastened in the first recess and fasten a second add-on board having a second height profile parallel to the system board in the computer system.

### TECHNICAL FIELD

This disclosure relates to a computer system including a casing having at least one casing wall, the at least one casing wall having a recess for attaching an add-on board, and a retaining device and an assembly method for an add-on board in a computer system.

### BACKGROUND

Computer casings usually have recesses in casing walls in which add-on boards such as PCI (Peripheral Component Interconnect) or PCIe (Peripheral Component Interconnect Express) cards can be installed into a computer system. Such PCI or PCIe cards are, for example, network cards or graphics cards. Add-on boards of this type have different form factors. For example, there are so-called low-profile boards whose slot frames are 79.2 mm high. There are also, for example, so-called full-height boards whose slot frames have a height of 120 mm. Depending on whether an add-on board is to be installed according to the low-profile or full-height form factor, the casings must have different recesses for fastening the add-on board. This results in high production expenditures, as different casings have to be produced according to requirements. In addition, this leads to low flexibility when retrofitting add-on boards with different form factors.

### SUMMARY

We provide a computer system including a casing having at least one casing wall, the at least one casing wall including a first recess for attaching a first add-on board having a first height profile; a system board arranged in the casing and extending perpendicular to the at least one casing wall, the first recess in the at least one casing wall extending perpendicular to the system board; and a retaining device adapted to be fastened in the first recess and fasten a second add-on board having a second height profile parallel to the system board in the computer system.

We also provide a retaining device adapted to be fastened in a recess for a first add-on board having a first height profile, the recess provided in a casing wall of a casing of a computer system, and to fasten a second add-on board having a second height profile in the computer system parallel to a system board arranged in the casing of the computer system.

We further provide an assembly method for an add-on board in a computer system including a casing having at least one casing wall, wherein the at least one casing wall includes a first recess for attaching a first add-on board having a first height profile, the assembly method including removing a detachable part, adjoining the first recess, from the at least one casing wall to form an aperture in the at least one first casing wall; fastening a retaining device for the second add-on board in the first recess so that a part of the retaining device extending parallel to the at least one casing wall is supported in the aperture; and fastening the second add-on board having the second height profile to the retaining device to be parallel to a system board arranged in the casing of the computer system.

### BRIEF DESCRIPTION OF THE DRAWINGS

FIG. 1 shows a perspective representation of a computer system according to an example in a first system configuration.

FIG. 2 shows a perspective representation of the computer system according to the example shown in FIG. 1, in a second system configuration.

FIG. 3 shows a partially exploded representation of a section of the computer system according to the second system configuration according to FIG. 2.

FIG. 4 shows a cross section of a section of the computer system according to the second system configuration according to FIG. 2.

FIG. 5 shows a section of the first casing wall of a computer system according to an example.

### List of Reference Numerals

1 computer system

2 low-profile board

3 full-height board

4 casing

5 casing bottom

6 first casing wall

7 second casing wall

8 system board

9 memory module

10 processor

11 heat sink

12 first recess

13 second recess

14 slot frame of the low-profile board

15 retaining device

16 fastening part

17 board mount

18 slot frame of the full-height board

19 aperture

20 detachable part

21 connecting part

22 connector

23 mating connector

24 connector

25 mating connector

26 break-off part

27 lug

28 protrusion

29 mounting plate

A first system configuration

B second system configuration

S section line

### DETAILED DESCRIPTION

Our computer system may include a casing having at least one casing wall. The at least one casing wall comprises a first recess for attaching a first add-on board having a first height profile. The computer system may further include a system board arranged in the casing and extending perpendicular to the at least one casing wall. The first recess in the at least one casing wall extends perpendicular to the system board. The computer system also may include a retaining device adapted to be fastened in the first recess and to fasten a second add-on board having a second height profile parallel to the system board in the computer system.

It is advantageous that add-on boards having different height profiles can be fastened in the first recess of the casing wall. In particular, low-profile boards as well as full-height boards can be fastened in a recess provided for low-profile boards. Depending on the requirements of the user of the computer system, a corresponding add-on board can be installed without the need to produce differently designed casings.

The height of the retaining device perpendicular to the system board may correspond to the height of the first add-on board. Furthermore, the retaining device may comprise a fastening part provided for the second add-on board and arranged on an end of the retaining device facing away from the system board.

One advantage is that the second add-on board that can be fastened parallel to the system board in the computer system is attached as far away from the system board as possible. This ensures a good cooling of the system board, the second add-on board as well as other components attached in the computer system. This also ensures as much space as possible for attaching components to the system board, even if the second add-on board is installed in the computer system.

The at least one casing wall may comprise at least one second recess adapted to receive a first add-on board having a first height profile when the retaining device is fastened in the first recess.

Thus, different add-on boards with different form factors can be installed into the computer system. In particular, for example, an add-on board according to the low-profile standard and an add-on board according to the full-height standard can be installed.

The at least one casing wall may include a break-off part that adjoins the first recess and is adapted to open an aperture in which a part of the retaining device extending parallel to the at least one casing wall can be supported. The advantage is that a casing with such a break-off part is relatively easy and inexpensive to produce.

The at least one casing wall may comprise an aperture that adjoins the first recess and in which a part of the retaining device extending parallel to the at least one casing wall can be supported. The aperture may be adapted to be covered with a blind if the computer system is adapted to attach the first add-on board having the first height profile in the first recess.

For example, screwed or clip-mounted sheet metal parts or plastic parts are suitable for the blind. One advantage of such a blind is that it can be flexibly removed and reattached, depending on whether an add-on board with the first or second height profile is installed in the computer system.

A retaining device may be adapted to be fastened in a recess for a first add-on board having a first height profile, the recess being provided in a casing wall of a casing of a computer system, and to fasten a second add-on board having a second height profile in the computer system parallel to a system board arranged in the casing of the computer system.

An assembly method for an add-on board in a computer system may comprise a casing having at least one casing wall, wherein the at least one casing wall comprises a first recess for attaching a first add-on board having a first height profile. The assembly method may comprise the following steps: removing a detachable part, adjoining the first recess, from the at least one casing wall to form an aperture in the at least one first casing wall; fastening a retaining device for the second add-on board in the first recess so that a part of the retaining device extending parallel to the at least one casing wall is supported in the aperture; and fastening the second add-on board having the second height profile to the retaining device to be parallel to a system board arranged in the casing of the computer system.

The detachable part of the at least one casing wall may be, for example, a break-off part that is broken out of the at least one casing wall, or a detachable blind made, for example, of sheet metal or plastic and to which at least one casing wall can be fastened, for example, by screws or clip connections.

Further advantages and configurations are disclosed in the following description of the Figures. In the Figures, the same reference signs are used for elements with essentially the same function, but these elements do not have to be identical in all details.

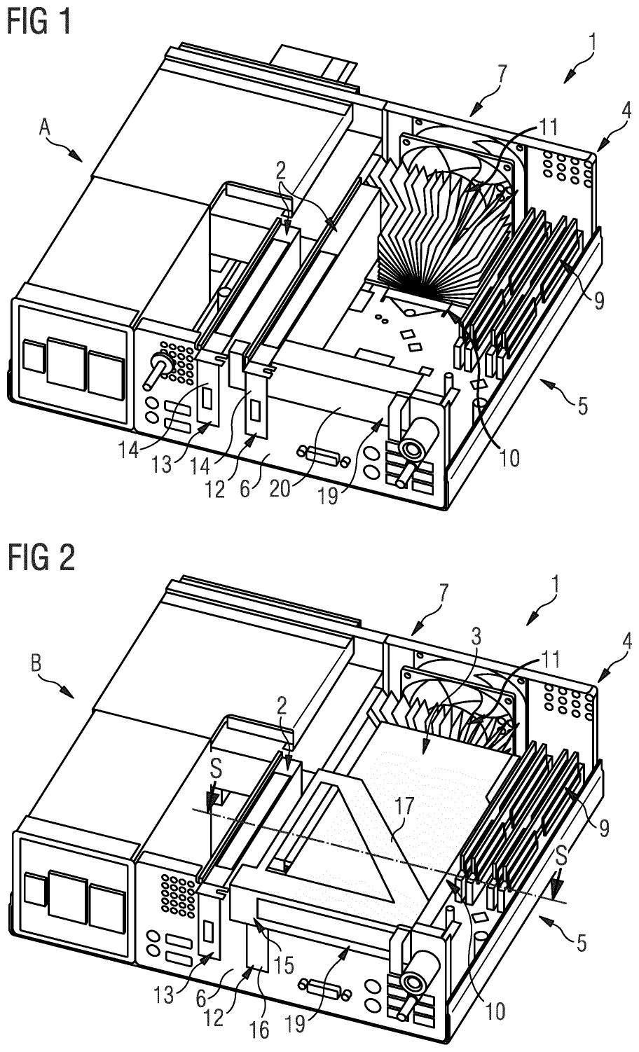

FIGS. 1 and 2 each show a perspective view of a computer system 1 according to an example. FIG. 1 shows the computer system 1 in a first system configuration A, FIG. 2 shows the computer system 1 in a second system configuration B. The first system configuration A according to FIG. 1 is characterized in that two low-profile boards 2 are installed in the computer system 1. The second system configuration B according to FIG. 2 is characterized in that one low-profile board 2 and one full-height board 3 are installed in the computer system 1.

The computer system 1 according to FIGS. 1 and 2 each comprise a casing 4. The casing 4 in this example is a casing with a small form factor (SFF), which has a volume of about 8 liters. Alternatively, the system herein can of course also be used in any computer casing. The casing 4 has a casing bottom 5. At opposite side edges of the casing bottom 5, a first casing wall 6 and a second casing wall 7 protrude vertically from the casing bottom 5. The computer system 1 can be closed with a casing lid (not shown here).

Parallel to the casing bottom 5, a system board 8 is installed in the computer system 1. The system board 8 is located in an area of the casing bottom 5 and is fastened to the casing bottom by screws (not shown here). The system board 8 is equipped with various components such as memory modules 9, a processor 10 and a heat sink 11.

A first recess 12 and a second recess 13 are provided in the first casing wall 6. The first and second recess 12, 13 each extend in a slit-shaped manner from an end of the first casing wall 6 facing away from the casing bottom 5 to be perpendicular to the system board 8.

According to the first system configuration A shown in FIG. 1, a low-profile board 2 is fastened in each of the first and second recesses 12, 13. The low-profile boards 2 each have a slot frame 14 used to fasten the low-profile boards 2 in the first and second recesses 12, 13 respectively. The low-profile boards 2 are arranged perpendicular to the system board 8 and fitted onto the system board 8. The low-profile boards 2 have different lengths in this example. Alternatively, low-profile boards 2 of equal length can of course also be used.

According to the second system configuration B shown in FIG. 2, a low-profile board 2 is only fastened in the second recess 13. According to the second system configuration B, a retaining device 15 for a full-height board 3 is attached in the first recess 12. To provide sufficient space for the full-height board 3 in the computer system 1, cooling fins of the heat sink 11 have corresponding recesses.

The retaining device 15 has a fastening part 16 by which the retaining device 15 is fastened in the first recess 12. The retaining device 15 also has a board mount 17, to which the full-height board 3 is attached to the retaining device 15 by a slot frame 18 of the full-height board 3. The board mount 17 is designed in a triangular shape above one side of the full-height board 3 facing away from the system board 8 that serves to strengthen and protect the board 3.

The board mount 17 is fastened in an aperture 19 of the first casing wall 6. The aperture 19 adjoins the first recess 12 and is open at an end of the first casing wall 6 opposite the casing bottom 5. The aperture 19, in which the board mount 17 is supported, extends parallel to the system board 8 and perpendicular to the first and second recess 12, 13. Accordingly, the slot frame 18 of the full-height board 3, and thus also the full-height board itself, is fastened to be parallel to the system board 8 in the computer system 1.

The aperture 19 is covered in the first system configuration A according to FIG. 1 by a detachable part 20 of the first casing wall 6. The detachable part 20 is attached to the remaining first casing wall 6 with screws (not shown here). Alternatively, the detachable part 20 can also be fastened to the remaining first casing wall 6 using a clip connection. Thus, the detachable part 20 can be dismantled from the remaining first casing wall 6 and attached to it again. This allows a flexible change between the first system configuration A and the second system configuration B. The detachable part 20 represents a blind which is made of sheet metal, for instance, and seals the aperture 19 against electromagnetic radiation. Alternatively, the blind can also be made of plastic. An alternative configuration for this is described with reference to FIG. 5. In the first system configuration A, the detachable part 20 protects an interior of the casing 4, in an area of the aperture 19, from penetrating dust, and shields the casing 4 from electromagnetic radiation.

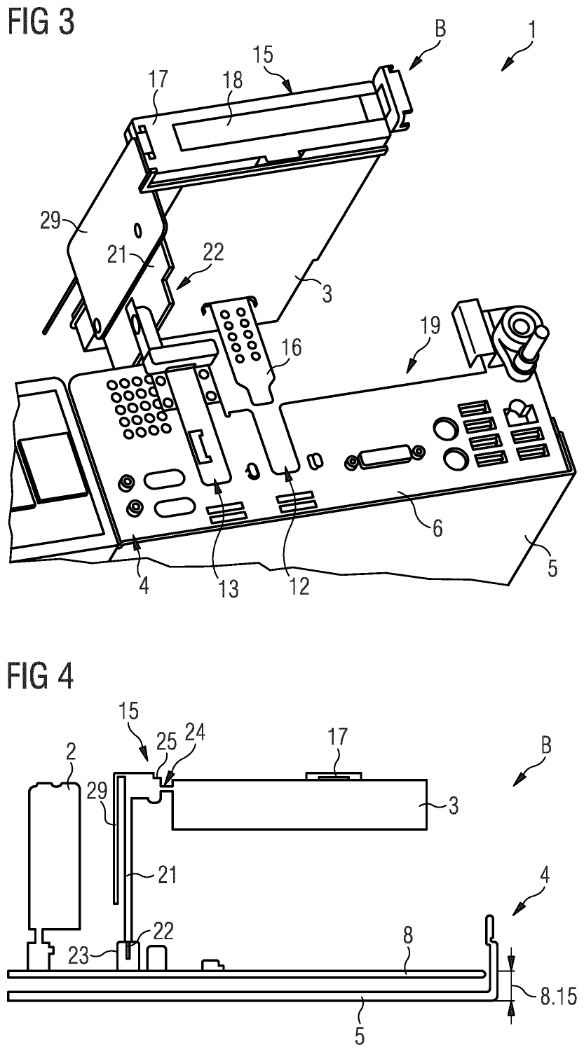

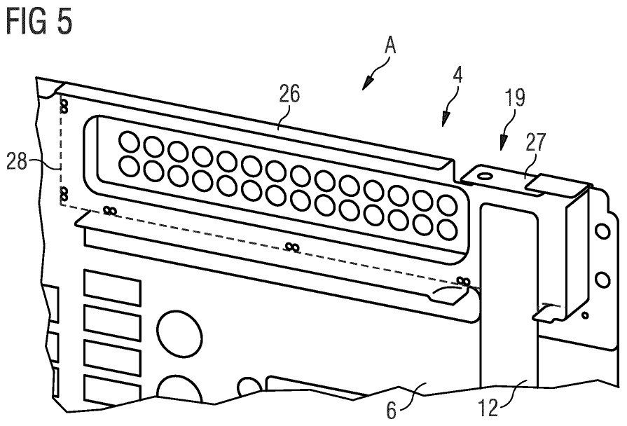

Further details regarding the retaining device 15 are described with reference to FIGS. 3 and 4.

FIG. 3 shows a partially exploded representation of a section of the computer system 1 according to the example according to FIGS. 1 and 2 in the second system configuration B. The section in FIG. 3 shows the casing bottom 5 and a part of the first casing wall 6 comprising the second recess 13 and the first recess 12 comprising the retaining device 15.

The fastening part 16, by which the retaining device 15 is fastened in the first recess 12, essentially resembles a lower end of a slot frame of a low-profile board 2 and is fastened to the board mount 17 of the retaining device 15 by screws (not shown here). Alternatively, the fastening part 16 is fastened to the board mount 17 not by screws, but is loosely connected to the board mount 17, for example, via a plug connection or only via a support contact.

The fastening part 16 serves, among other things, to seal the first recess 12 against electromagnetic radiation when the retaining device 15 is fastened in the first recess 12. Furthermore, it is possible to arrange an I/O interface (input/output interface), for example, a socket for a data interface, in the fastening part 16. This I/O interface may be an I/O interface connected to the full-height board 3, or can be any other I/O interface of the computer system 1.

FIG. 3 also shows a connecting part 21 of retaining device 15. This connecting part 21 extends perpendicular to the full-height board 3 in the direction toward the system board 8. When installed, the connecting part 21 is parallel to the low-profile board 2 shown in FIG. 2. The connecting part 21 represents a so-called riser card for the full-height board 3.

At an end of the connecting part 21 facing the system board 8, the connecting part 21 has a connector 22 according to the PCI or PCIe standard so that the connecting part 21 can be plugged with the connector 22 into a dedicated mating connector on the system board 8. This is explained in more detail below with reference to FIG. 4.

FIG. 4 shows a section through the computer system 1 according to the example according to FIGS. 1 and 2 in the second system configuration B. FIG. 5 shows a section plane parallel to the first casing wall 6 along a section line S shown in FIG. 2.

In the sectional view according to FIG. 4, a part of the casing bottom 5 and the system board 8 is shown. FIG. 5 also shows the low-profile board 2 and the full-height board 3 fastened in board mount 17. Furthermore, the connecting part 21 perpendicular to the system board 8 is shown. FIG. 4 also shows a mounting plate 29 to the left of the connecting part 21, which is part of a mechanical fastening of the retaining device 15.

FIG. 4 also shows the connector 22 of the connecting part 21 plugged into the mating connector 23 on the system board 8. The mating connector 23 that receives the connector 22 in the second system configuration B receives a corresponding connector of the low-profile board, which is fixed in the first recess, in the first system configuration A.

At an end of the connecting part 21 facing the full-height board 3, it has a mating connector 25 according to the PCI or PCIe standard. A corresponding connector 24 of the full-height board 3 is plugged into this mating connector 25 of the connecting part 21. In this way, an electrical connection for supply voltages, signals and the like is established between the system board 8 and the full-height board 3 via the connecting part 21.

FIG. 5 shows a section of the first casing wall 6 in an area of the aperture 19 together with a portion of the first recess 12. FIG. 5 shows a view of the first casing wall 6 as seen from an interior of the casing 4 of the computer system 1. FIG. 5 shows an alternative configuration to the detachable part 20 and the aperture 19. The state shown in FIG. 5 corresponds to the first system configuration A, according to which a low-profile board 2 can be fastened in the first recess 12.

In this example, the aperture 19 is covered by a break-off part 26. The break-off part 26 has a lug 27 at an edge zone of the first casing wall 6, to which a slot frame 14 of a low-profile board 2 can be fastened. If a full-height board 3 is to be installed in the casing 4 in the first recess 12, the break-off part 26 can be broken out of the casing wall 6. To this end, the casing wall 6 has a predetermined breaking line 28 along which the break-off part 26 can be severed from the first casing wall 6.

In addition, FIG. 5 shows a protrusion 28 attached along an upper edge of the aperture 19. This protrusion 28 points into the interior of the casing 4 and represents a support for the retaining device 15. This protrusion 28 can be used in similar manner as in the example according to FIGS. 1 to 4.

The examples shown in the Figures each having a first and a second recess 12, 13 are to be understood as examples only. Alternatively, the casing 4 or the first casing wall 6 may also comprise only the first recess 12 or further recesses similar to the first and second recesses 12, 13.

1.-10. (canceled)

11. A computer system comprising:
a casing having at least one casing wall, the at least one casing wall comprising a first recess for attaching a first add-on board having a first height profile;
a system board arranged in the casing and extending perpendicular to the at least one casing wall, the first recess in the at least one casing wall extending perpendicular to the system board; and
a retaining device adapted to be fastened in the first recess and fasten a second add-on board having a second height profile parallel to the system board in the computer system.

12. The computer system according to claim 11, wherein the first add-on board and the second add-on board is a PCI board and/or a PCIe board.

13. The computer system according to claim 12, wherein
the first add-on board is a low-profile board,
the second add-on board is a full-height board, and
the first recess is a low-profile slot.

14. The computer system according to claim 11, wherein a height of the retaining device perpendicular to the system board corresponds to a height of the first add-on board, and the retaining device comprises a fastening part provided for the second add-on board and arranged on an end of the retaining device facing away from the system board.

15. The computer system according to claim 11, wherein the at least one casing wall comprises at least one second recess adapted to receive a first add-on board having a first height profile when the retaining device is fastened in the first recess.

16. The computer system according to claim 11, wherein the retaining device includes a connecting part extending perpendicular to the system board and the at least one casing wall and is adapted to establish an electrical connection between the system board and the second add-on board.

17. The computer system according to claim 11, wherein the at least one casing wall includes a break-off part that adjoins the first recess and is adapted to open an aperture in which a part of the retaining device extending parallel to the at least one casing wall can be supported.

18. The computer system according to claim 11, wherein the at least one casing wall comprises an aperture that adjoins the first recess and in which a part of the retaining device extending parallel to the at least one casing wall can be supported, and the aperture is adapted to be covered with a blind if the computer system is adapted to attach the first add-on board having the first height profile in the first recess.

19. A retaining device adapted to be fastened in a recess for a first add-on board having a first height profile, the recess provided in a casing wall of a casing of a computer system, and to fasten a second add-on board having a second height profile in the computer system parallel to a system board arranged in the casing of the computer system.

20. An assembly method for an add-on board in a computer system comprising a casing having at least one casing wall, wherein the at least one casing wall comprises a first recess for attaching a first add-on board having a first height profile, the assembly method comprising:
removing a detachable part, adjoining the first recess, from the at least one casing wall to form an aperture in the at least one first casing wall;
fastening a retaining device for the second add-on board in the first recess so that a part of the retaining device extending parallel to the at least one casing wall is supported in the aperture; and
fastening the second add-on board having the second height profile to the retaining device to be parallel to a system board arranged in the casing of the computer system.
